(19) United States
(12) Patent Application Publication
(10) Pub. No.: US 2008/0273364 A1
(43) Pub. Date: Nov. 6, 2008

(54) MEMORY STRUCTURE WITH EMBEDED MULTI-TYPE MEMORY

(75) Inventor: Ling-Chiang Chao, Hsinchu City (TW)

Correspondence Address: J C PATENTS, INC., 4 VENTURE, SUITE 250, IRVINE, CA, 92618, US

(73) Assignee: MACRONIX INTERNATIONAL CO., LTD., Hsinchu (TW)

(21) Appl. No.: 12/061,149

(22) Filed: Apr. 2, 2008

Related U.S. Application Data
(60) Provisional application No. 60/915,935, filed on May 4, 2007.

(51) Int. Cl. G11C 5/06; G11C 5/02

(52) U.S. Cl. 365/51; 365/63

(57) ABSTRACT

A memory includes a first-type memory; and a second-type memory, formed on the first-type memory, wherein the first-type memory is a nonvolatile memory with a stack of conductor/storage/conductor, and the second-type memory is a nonvolatile memory, a flash memory or another memory with a stack of conductor/storage/conductor. In addition, the nonvolatile memory can include a storage element for each memory cell, including a bottom electrode layer; a memory material layer, disposed over the bottom electrode layer, wherein the memory material has at least two physical states under different electric operation condition; and a top electrode layer, disposed over the memory material layer.

### CROSS-REFERENCE TO RELATED APPLICATION

This application claims the priority benefit of U.S.A. provisional application Ser. No. 60/915,935, filed on May 4, 2007. The entirety of the above-mentioned patent application is hereby incorporated by reference herein and made a part of this specification.

### BACKGROUND OF THE INVENTION

1. Field of Invention

The present invention relates to a memory structure. More particularly, the present invention relates to a memory structure with multiple types of memories, including volatile memory and non-volatile memory.

2. Description of Related Art

It is well known that memory can be generally divided into volatile memory and non-volatile memory. The volatile memory includes, for example, RAM, in which the stored information disappears when the power is off. However, the operation speed is relatively fast and the endurance thereof is very high. The non-volatile memory includes, for example, flash memory, in which the stored information remains when power is off. However, the operations speed is relatively slow and the endurance is relatively low as well. Since the properties between volatile memory and non-volatile memory are different, they are usually separately fabricated though different process in different chips. Each chip occupies a device area on the PCB.

Both types of memory are commonly used in electronic system or electronic apparatus. The volatile memory can store some temporarily produced data during operation while the non-volatile memory can, for example, store some operation programs, such as firmware. In further applications, various mobile electronic apparatus, such as mobile phone, have been the very common products in use. In order to improve the function of the mobile electronic apparatus, it needs the non-volatile memory to store the firmware and the volatile memory to store some temporarily produced data.

If the volatile memory and the non-volatile memory fabricated in separate chips are needed in a single application, it causes the use of a PCB of a larger size, and therefore renders the size reduction of the mobile apparatus to be difficult. In order to reduce the area of PCB, a multi-chip package (MCP) technology is proposed. The MCP technology is based on the packaging technology to pack one non-volatile memory onto another volatile memory. However, each type of memories is separately fabricated and is packaged later based on packaging process, as shown in FIG. 1. The conventional MCP memory structure 100 includes, for example, a SRAM chip 102 and a flash chip 104, which are packed in stack 108 by the MCP technology. The I/O pins 106 are also need to further arrangement in packaging process. This conventional MCP memory causes high fabrication cost.

### SUMMARY OF THE INVENTION

The invention provides a multiple-type memory device fabricated together under a sequence of semiconductor fabrication process without basing on packaging process. The multiple-type memory device in the embedded structure can save the device volume and make the operation in more efficiency. In addition, the device is not mainly based on packaging process to integrate different types of memory, the fabrication process and cost can be reduced as well.

The present invention provides a memory includes a first-type memory; and a second-type memory, formed on the first-type memory. The first-type memory can be a volatile memory or a nonvolatile memory with a stack memory structure of conductor/storage/conductor, and the second-type memory is a nonvolatile memory, a flash memory or another memory with a stack of conductor/storage/conductor.

In addition, the non-volatile memory can include a storage element for each memory cell, including a bottom electrode layer; a memory material layer, disposed over the bottom electrode layer, wherein the memory material has at least two physical states under different electric operation condition; and a top electrode layer, disposed over the memory material layer.

The present invention further provides an electric apparatus, comprising a main circuit part; and a memory part, used by the main circuit part for storing binary data or multilevel data. The memory part comprises a first-type memory; and a second-type memory, formed on the first-type memory. The first-type memory can be a volatile memory or a non-volatile memory with a memory structure of a stack of conductor/storage/conductor, and the second-type memory is a nonvolatile memory, flash memory or another memory with a stack of conductor/storage/conductor.

The present invention further provides a memory structure, comprising a memory structural base, formed over a substrate, wherein the memory structural base has a planarized dielectric layer on top. A plurality of first electrode layers is disposed over the dielectric layer. A plurality of memory material layers is disposed on the first electrode layers at predetermined positions. A plurality of second electrode layers is disposed on the memory material layers, to form a plurality of memory cells. An inter-metal dielectric layer is disposed over the memory cells. A plurality of conductive lines, serving as bit lines, is disposed over the inter-metal dielectric layer. A plurality of conductive via is disposed in the inter-metal dielectric layer for respectively connecting the memory cells to the corresponding bit lines.

The present invention further provides a memory structure, comprising a structure base disposed over a substrate, wherein the structure base comprises a plurality of switch transistors and a plurality of word lines, the word lines control the switch transistors to couple to a ground voltage. A dielectric layer is disposed over the structure base. A plurality of first electrode layers is disposed over the dielectric layer. A plurality of memory material layers is disposed on the first electrode layers at predetermined positions. A plurality of second electrode layers is disposed on the memory material layers, to form a plurality of memory cells. An inter-metal dielectric layer is disposed over the memory cells. A plurality of conductive lines, serving as bit lines, is disposed over the inter-metal dielectric layer. A plurality of conductive via is disposed in the inter-metal dielectric layer for respectively connecting the memory cells to the corresponding bit lines, to form a first memory.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a cross-sectional view, schematically illustrating a conventional package structure with two different types of memory.

FIG. 2 is a cross-sectional view, schematically illustrating a package structure with two embedded different types of memory, according to an embodiment of the present invention.

FIG. 3 is a top view, schematically illustrating a memory layout for a PCRAM.

FIG. 4 is a cross-sectional view, schematically illustrating a structure of a memory of conductor-storage-conductor type, according to an embodiment of the present invention.

FIG. 5 is a cross-sectional view, schematically illustrating a semiconductor structure of a memory of conductor-storage-conductor type, according to an embodiment of the present invention.

FIG. 6 is a perspective view, schematically illustrating a stack structure for the memory of conductor-storage-conductor type, according to an embodiment of the present invention.

FIG. 7 is a drawing, schematically illustrating a part of equivalent circuit for the memory cell, according to an embodiment of the present invention.

FIGS. 8-12 are drawing, schematically illustrating the properties of storage materials in resistive-type, according to an embodiment of the present invention.

FIG. 13 is a circuit, schematically illustrating circuit structure for a memory with multi-type embedded memory, according to an embodiment of the present invention.

FIG. 14 is a circuit, schematically illustrating circuit structure for a memory with multi-type embedded memory, according to another embodiment of the present invention.

FIGS. 15A-15C are cross-sectional views, schematically illustrating a fabrication process to form a memory with multi-type embedded memory, according to another embodiment of the present invention.

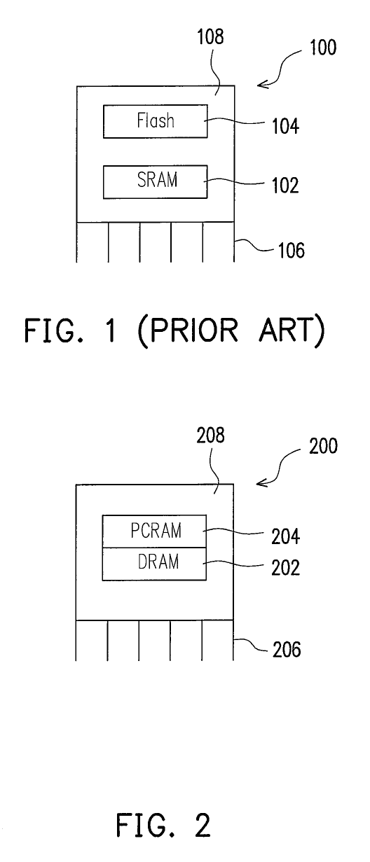

### DESCRIPTION OF THE PREFERRED EMBODIMENTS

In the invention, as for example shown in FIG. 2, a memory structure 200 includes a first memory 202, including volatile memory such as DRAM, SRAM, PSRAM or the like, or nonvolatile memory such as data flash, and a second memory 204 of a conductor-storage-conductor type, such as a nonvolatile memory like phase change RAM (PCRAM) formed above the first memory. It should be noted that the second memory 204 is directly fabricated on the first memory 202 not based on the packaging process. Here, the second memory 204 is, for example, a PCRAM. However, the nonvolatile can be other structure, such as anti-fuse memory. Preferable, the memory cell of the nonvolatile memory 204 includes a bottom electrode layer and top electrode layer, and a memory material or a storage element between the two electrodes. Due to different operation conductions such as voltages or currents, the property of the memory material has changed in different state, so that the states can be used to store a binary data or multilevel data. After the first memory 202 and the second memory 204 are formed together based on the semiconductor fabrication process but not based on packaging process, the integrated device of multiple-memory is packaged by the usual packaging process to form the IC package 208 with the I/O pins 206.

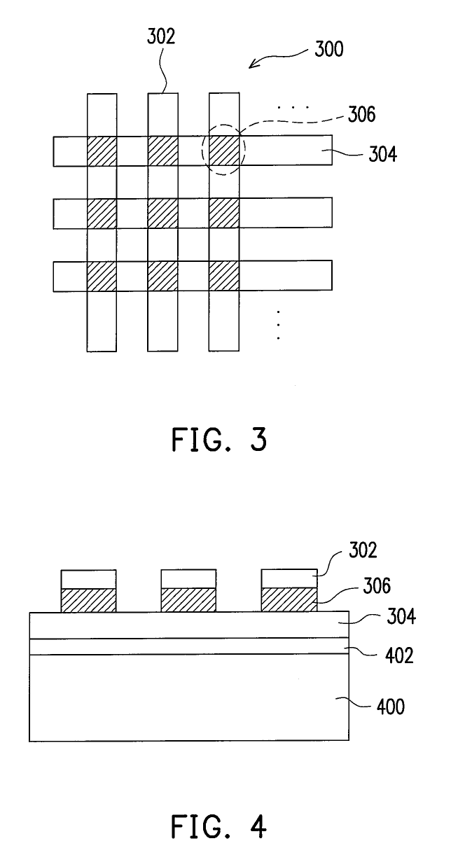

FIG. 3 is a top view, schematically illustrating a memory layout for a PCRAM. The PCRAM layout 300 includes several top electrode lines 302, for example, extending along one direction. Several bottom electrode lines 304, for example, extending along another direction not in parallel to the first direction, to form intersections with the top electrode lines 302. The memory material layers or storage element 306 are respectively disposed at the intersection areas between the top electrode lines 302 and the bottom electrode lines 304. FIG. 4 is a cross-sectional view, schematically illustrating a structure of the present invention. In FIG. 4, for example, a nonvolatile memory is formed over a volatile memory 400, which can be, for example, DRAM, SRAM, PSRAM . . . and so on. The volatile memory 400 serves as a structure substrate for forming the non-volatile memory. In order to have isolation, if it is necessary, a dielectric layer 402 is formed over the volatile memory 400. Then, a bottom electrode line layer 304 is formed over the volatile memory 400, for example, on the dielectric layer 402. A memory material layer 306 is formed on the bottom electrode line layer 304 at the positions, at which a memory cell is to be formed. Then, a top electrode line layer 302 is formed over the memory material layer 306 and intersects with the bottom electrode line layer 304. Here, the top electrode line layer 302 and the bottom electrode line layer 306 are naturally isolated. It should also be noted that the basic structure is shown in FIG. 3 without showing the full circuit of the memory. However, the additional circuit can be understood by the person with ordinary skill and can be formed based on the semiconductor fabrication process.

The memory material layer 306 is, for example, a chalcogenide material with the physical properties that the crystal phase can be changed at a corresponding critical temperature. The different crystal phase can present different resistance states. According to different resistance states, the binary data in “0” or “1” can be stored. The desired temperature can be obtained by applying the current on the memory element, which serves as a resistor with resistance states.

Further, the PCRAM is not the only choice, the memory material layer 306 can be insulation fuse, or called anti-fuse, serving as an one-time-programmable memory. In other words, when the insulation fuse remains intact, there is no electrical connection between the bottom electrode and the top electrode, resulting in a stored data of, i.e. “0”. However, when the insulation fuse is burnt through, then an electrical connection between the bottom electrode and the top electrode is established, resulting in another storing data, i.e., “1”. The PCRAM technology can also be referred to U.S. Publications No. 2006/0286709, 2006/0284279, 2006/0284214, 2006/0284158, 2006/0284157, and 2005/0041467.

It should be also noted that the memory cell is operated between two electrodes, so that the memory cells is not necessary to be just one cell. For PCRAM, a magnitude variation of resistors can be changed adding heat. Therefore, it is possible to reach multiple levels operation. Besides, stack method is also applied to stack a plurality of memory in the vertical direction in order to save the effective area in the wafer and increasing memory density at the same time. Actually, many memory cells can be vertically stacked, resulting in save of available active area on the wafer.

Like PCRAM, other nonvolatile memory with similar structure of conductor-storage-conductor type, such as magnetoresistive random access memory (MRAM) or resistive random access memory (RRAM) can also be implemented. The MRAM cell, as can be understood, has the ferromagnetic-storage stack layer as the memory cell, such as the MTJ cell in i.e. toggle-mode operation, between a top conducting line and a lower conducting line. When the top conducting line and a lower conducting line are applied proper current, a magnetic field in the desired direction can be created. The MTJ cell basically includes a pin layer, an isolation layer, and a free layer has a permanent magnetization direction while a free layer has the changeable magnetization direction. When the created magnetic field is applied to the MTJ cell to change the magnetization direction in free layer, it causes parallel or anti-parallel to the magnetization of the pin layer, resulting to different magnetoresistive level, which can store the binary information. Therefore, the MRAM can be directly fabricated over another memory in one fabrication process but not by packaging process.

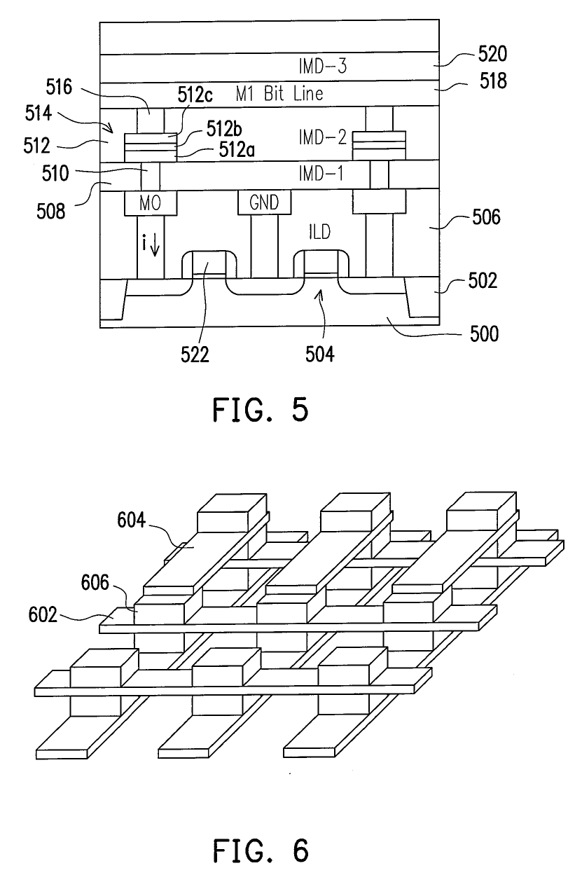

In addition, the RRAM is also a structure of conductor-storage-conductor. The RRAM cell includes a transistor and a resistive element. The resistive element has a basic structure of metal/resistance layer/metal (MRM). Based on semiconductor fabrication, as for example shown in FIG. 5, a wafer substrate 500 serves as a substrate having the isolation trench 502. Transistors 504 are formed between the isolation trench 502. In this example, two memory cells shares one common ground GND. Each transistor 504 has a gate 522. The gate 522 can be, for example, coupled to word line WL. An inter-layer dielectric (ILD) layer 506 is disposed over the transistors 504. Interconnection structure, including several contacts are formed in the inter-layer dielectric layer 506 to connect between the ground (GND) and the source/drain region of the transistors 504; and between the electrode terminal (MO) and the source/drain region of the corresponding one of the transistors 504. Depending on the interconnect structure, another inter-metal dielectric (IMD) layer 508 may be further formed over the inter-layer dielectric layer 506. The resistive-type storage element 512 is formed on the IMD layer 508 with a via 510 to be coupled to the electrode terminal (MO), and then to the source/drain region of the corresponding transistor 504. The resistive-type storage element 512 includes, for example, a resistive storage layer 512b and the two electrodes 512a, 512b on top and bottom. Another IMD layer 514 is formed surround the storage elements. Conductive vias 516 are respectively formed in the IMD layer 514 to connect to the upper electrode. Then a bit line 516 is formed over the IMD layer 514 with electric connection to the corresponding vias 516. Then, the subsequent IMD layer 520 is formed over the bit line 518. The further subsequent structure is not described here but it can be understood by one with ordinary skill in the art.

In FIG. 6, since the memory mechanism of the present invention is based on conductor-storage-conductor type, the storage element 606 can be stacked vertically, so as to save the horizontal active area and increase to memory capacity. In this example, two storage elements are stacked with sharing a common ground 602 (also see FIG. 5). In other words, the memory material layers at the predetermined positions are formed between the top electrode and the bottom electrode. By applying the operation voltages to the top electrode and the bottom electrode, the selected memory cell can be programmed and read. It should also be noted that the structure in FIG. 6 is the schematic drawing. The actual design can have more electrode layer in different height levels.

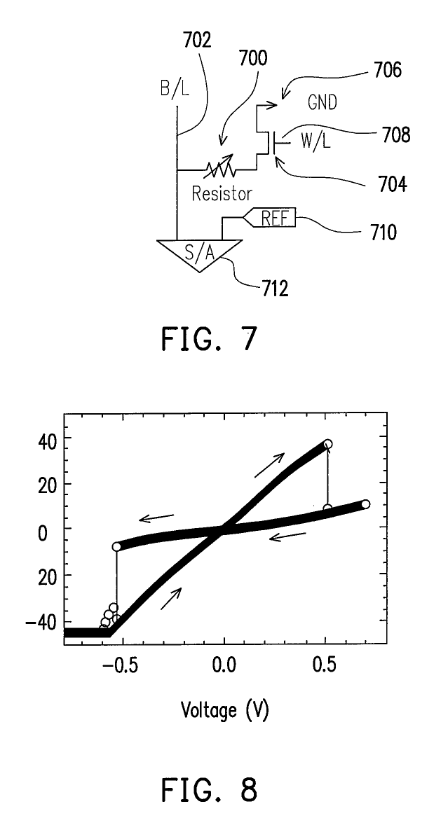

Further, the equivalent circuit of the memory cell in operation is shown in FIG. 7. In FIG. 7, the storage element 700 is coupled with a transistor 704 in series. The bit line (B/L) 702 is coupled to one terminal of the storage element 700 while the word line 708 is coupled to the gate of the transistor 704. The word line 708 can turn on the transistor 704 for conducting the storage element 700 to the ground voltage GND 706 while the bit line 702 is applied with a voltage. Depending on the voltage being applied, the read operation, programming operation and erasing operation can be performed on the selected memory cell by changing the property of the resistive material. The sense amplifier (SA) 712 can sense the different state voltage state by a reference voltage 710 to read the stored content.

Several resistive materials can be used for the resistive-type storage element. For example, SrZr(Ti)O₃, PrCaMnO₃, polymer, or dual-dimension oxide can be used. The relation between bias and current for the SrZr(Ti)O₃ material is shown in FIG. 8. Due to the energy levels of the donors or acceptors, the conductions of carriers in the insulating film during the voltage increasing and decreasing conditions have different I-V relations, so that the storage element can store the binary data.

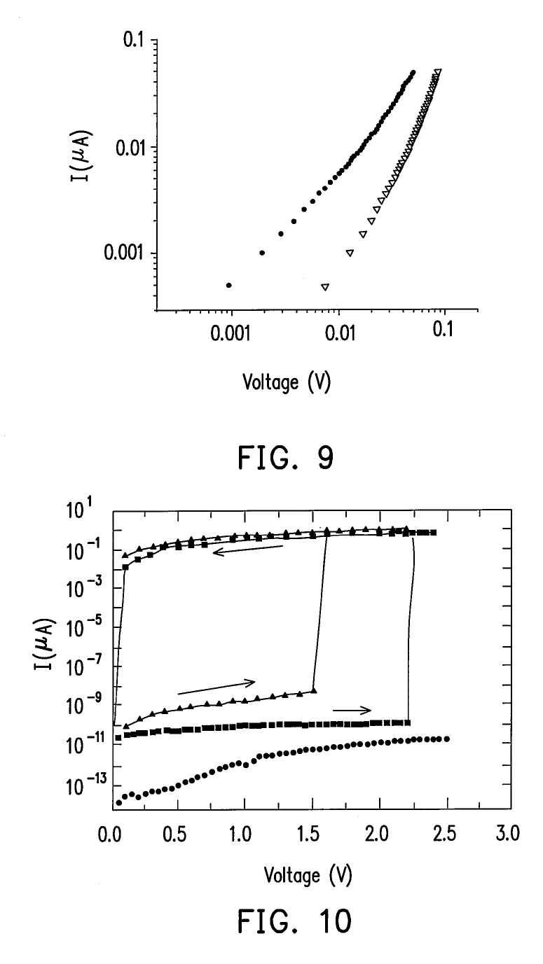

Similarly, the properties of I-V relation for the material PrCaMnO₃ is shown in FIG. 9. Again, two relation curves can be created, so as to store the binary data. The current mechanism is dominated by thermionic emission limited conduction at low voltage region, i.e. less than 0.1 volt. When the voltage is at the relative high voltage (i.e. greater than 0.5 Volt), then the mechanism is dominated by space-charge limited current.

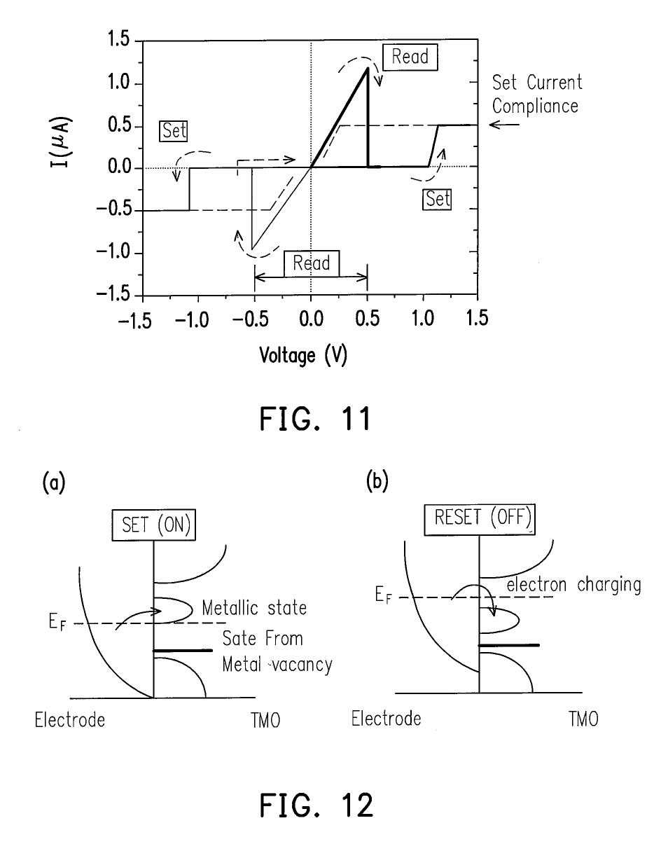

The I-V relation for the polymer is also shown in FIG. 10, the resistance can vary as high as 10⁹ times. The current is abruptly rising at high voltage region and the current is abruptly dropping at the low voltage region. This phenomenon can be used to store the binary data.

The dual-dimension oxide, such as nickel oxide, having different I-V relation in different operation voltage, as shown in FIG. 11. This kind of material film includes nickel oxide and nickel in coexistence by performing a reaction sputtering process and controlling the growing environment. The electric conduction theoretically is based on nickel vacancy. In order to get the electric neutral state for each nickel vacancy, two Ni²⁺ become two Ni³⁺. According to experimental result, if the concentration of vacancies of metallic Ni is relatively low, it cannot have a stable ON state. In theoretic interpretation, ON state is relating to metallic Ni defect with energy level close to the Fermi energy. In FIG. 12(a) When the OFF state is changed to ON state, the defects can be cleared with effect of releasing electrons. However, in FIG. 12(b), when the ON state is changed to OFF state, the vacancy at the defect is filled with electrons. The energy levels being fully filled with electrons contribute no conducting effect. As a result, the resistance is changed in two states for storing binary data.

In the foregoing four resistive materials, the DC bias can be used in operation. However, the voltage pulse can also be used. By modulating the amplitude of the pulse or the period, the resistance value can be accordingly changed for storing data.

In addition, a steering element such as a diode can be disposed between the top and bottom electrodes and electrically coupled to the storage element in series for controlling the direction of operations such as read and write.

Further to the invention, a shared controller circuit is disclosed. At least a portion of access control circuits of the first and second memories, such as addressing and decoder circuitries, can be combined and therefore shared by both memories to further reduce the real estate of the hybrid memory system of the present invention.

It should be noted that the nonvolatile memory is embedded in another type of memory, such as the volatile memory, or vice verse. In other words, the nonvolatile memory can be fabricated as a top memory or a bottom memory in the stacked memory. The foregoing example is just one of various options for describing the features of the present invention. As a result, at least two different types of memory are fabricated as an integrated chip without need of MCP technology. The nonvolatile memory and the volatile memory are not necessary to be limited to the foregoing embodiments. The number of memory types being embedded can be greater than 2, depending on the actual need. However, the present invention proposes a single chip having multiple types of memory, including volatile memory and nonvolatile memory. Preferably, the nonvolatile memory is not necessarily based on MOS structure, which needs source/drain and gate electrodes.

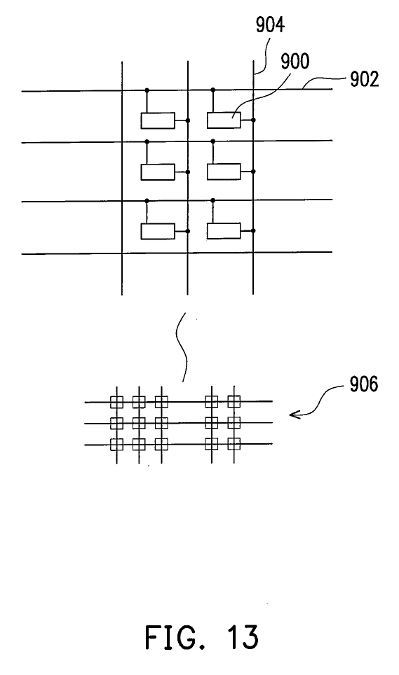

Based on the present invention, the circuit may be arranged in two layers for different memory types. FIG. 13 is a circuit, schematically illustrating circuit structure for a memory with multi-type embedded memory, according to an embodiment of the present invention. In FIG. 13, for example, the circuit layer of conductor-storage-conductor type memory is formed over a circuit layer of volatile memory 906 is serving. The circuit layer 906 of volatile memory has a cell array at formed from the intersection regions of the word lines and bit lines. The circuit layer of conductor-storage-conductor type memory is formed over the circuit layer 906 having conductive lines 902 and 904 with intersection. The conductive lines 902 and 904 serve as bit lines and word lines, coupled to top electrode and bottom electrode of memory element 900. Here, bit line and word line are just the usual terms being used for description without specific limitation. In this circuit, for example, the operation voltages can be applied to the conductive lines 902, 904 with one at an operation high voltage and another one at ground voltage.

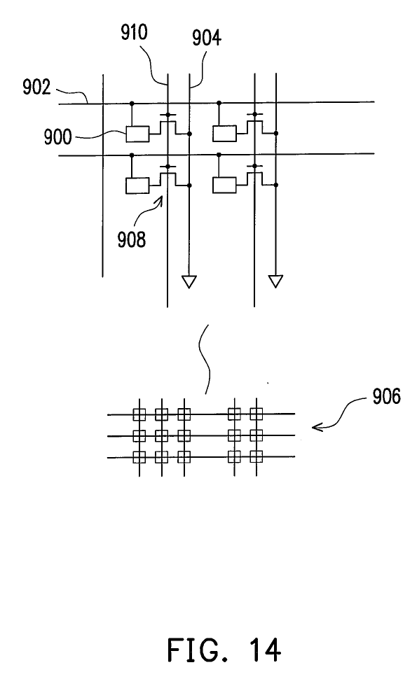

FIG. 14 is a circuit, schematically illustrating circuit structure for a memory with multi-type embedded memory, according to another embodiment of the present invention. In FIG. 14, alternatively, a switch transistor 908 can be used in control. In this manner, the gate of the transistor 908 can be connected to a word line 910, for example while one source/drain terminal is conned to ground voltage and bit line 902 by the conductive lines 904. The circuit layer of conductor/storage/conductor memory is formed above the circuit layer 906 of the volatile memory. When the switch transistor is turned on, then the ground voltage is passed to the memory element 900. In other words, the circuit layout can be arranged according to the actual design.

In the following descriptions, a semiconductor process is provided as the example to fabricate the memory device without using the packaging process at this stage.

Further, the memory of the present invention can be fabricated in the semiconductor process without additional packaging process. The fabrication cost can be reduced. FIGS. 16A-16C are cross-sectional views, schematically illustrating a fabrication process to form a memory with multi-type embedded memory, according to another embodiment of the present invention.

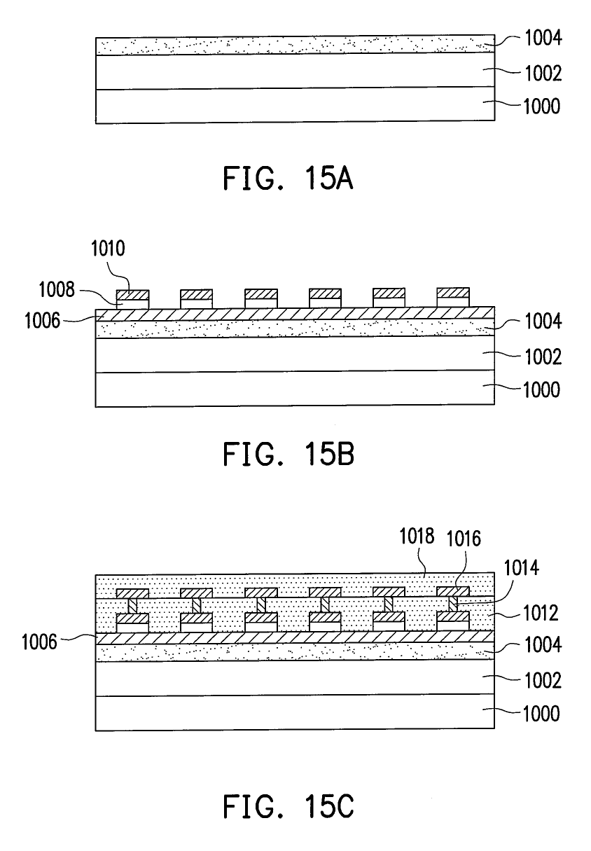

In FIG. 15A, for example, a volatile memory base 1002, such as a DRAM, has been formed over a substrate 1000. The volatile memory base 1002 has a planarized dielectric layer 1004 formed on top. In FIG. 15B, taking the dielectric layer 1004 as a base, a conductive layer 1006 is formed on the dielectric layer 1004. The conductive layer 1006 can be, for example, patterned into a stripe conductive layer. In this example, the conductive layer 1006 may also serve as a bottom electrode of the memory element of conductor-storage-conductor memory type. However, if it is necessary, the additional bottom electrode layer can be formed as well. A memory storage material layer 1008 is formed on the conductive layer 1006 at the predetermined positions. Atop electrode 1010 is formed on the storage material layer 1008. Here, the term of top electrode and bottom electrode are the terms for description without specific limitation in name. In addition, the memory material layer 1008 and electrode layer 1010 can be, for example, patterned in the same patterning process. However, the patterning process is a design choice to form the desired structure.

In FIG. 15C, an inter-metal dielectric layer (IMD) 1012 is formed over the substrate 1000 to cover the memory element. Several vias 1014 are formed in the inter-metal dielectric layer 1012 to respectively connect to the electrode layer 1010 and a conductive line 1016 in, for example, perpendicular direction to the conductive line 1006, is formed over the IMD layer 1012 in electric connection with the corresponding vias 1014. The conductive line 1016 can, for example, serve as the bit line. Then, another IMD layer 1018 is formed over the IMD layer 1012. Here, as can be understood by the one with ordinary skill in the art, the control circuit and the transistor with interconnection at other region of the substrate 1000 are also formed without specific descriptions. Further, the fabrication process is not the only choice. Depending on the more detail structure, the fabrication processes can be accordingly modified without beyond the scope of the present invention.

In other words, the present invention proposed the memory device with multi-type embedded memories, based on the semiconductor fabrication process but not on the packaging process. The present invention can reduce the memory size. Particularly, the present invention can at least reduce the sized of a mobile electronic device.

It will be apparent to those skilled in the art that various modifications and variations can be made to the structure of the present invention without departing from the scope or spirit of the invention. In view of the foregoing descriptions, it is intended that the present invention covers modifications and variations of this invention if they fall within the scope of the following claims and their equivalents.

What is claimed is:

1. A memory, comprising:
a first part circuit for a first-type memory; and
a second part circuit for a second-type memory, wherein the first part circuit and the second part circuit form an integrated circuit, and the first-type memory is a nonvolatile memory with a stack of conductor/storage/conductor, and the second-type memory is a volatile memory, a flash memory, or a memory with a stack of conductor/storage/conductor.

2. The memory as recited in claim 1, further comprising a packaging structure, over the integrated circuit to form a single memory chip.

3. The memory as recited in claim 1, wherein the nonvolatile memory comprises:
a storage element for each memory cell comprising:
a bottom electrode layer;
a memory material layer, disposed over the bottom electrode layer, wherein the memory material has at least two physical states under different electric operation condition; and
a top electrode layer, disposed over the memory material layer.

4. The memory as recited in claim 3, further comprising a steering element disposed between the top and bottom electrode layers and electrically coupled to the storage element in series for controlling a direction of operations in read and/or write.

5. The memory as recited in claim 1, wherein the nonvolatile memory includes PCRAM, anti-fuse memory, MRAM, RRAM, or like.

6. The memory as recited in claim 1, further comprising a memory in addition to the first-type memory and the second-type memory.

7. The memory as recited in claim 1, wherein the non-volatile memory comprises:
a plurality of electrode layers in different height levels;
a plurality of memory material layers, disposed between the electrode layers, wherein the memory material has at least two physical states under different electric operation condition.

8. The memory as recited in claim 7, further comprising a plurality of steering elements disposed between the electrode layers and each of the steering elements electrically coupled to a corresponding one of the storage elements in series for controlling a direction of operations in read and/or write.

9. An electric apparatus, comprising:
a main circuit part; and
a memory part, used by the main circuit part for storing binary data, wherein the memory part comprises:
a first part circuit for a first-type memory; and
a second part circuit for a second-type memory, wherein the first part circuit and the second part circuit form an integrated circuit, and the first-type memory is a nonvolatile memory with a stack of conductor/storage/conductor, and the second-type memory is a volatile memory, a flash memory or a memory with a stack of conductor/storage/conductor.

10. The electric apparatus as recited in claim 9, wherein the memory part further comprising a packaging structure, over the integrated circuit to form a single memory chip.

11. The electric apparatus as recited in claim 9, wherein the nonvolatile memory comprises:
a storage element for each memory cell comprising:
a bottom electrode layer;
a memory material layer, disposed over the bottom electrode layer, wherein the memory material has at least two physical states under different electric operation condition; and
a top electrode layer, disposed over the memory material layer.

12. The electric apparatus as recited in claim 11, further comprising a steering element disposed between the top and bottom electrode layers and electrically coupled to the storage element in series for controlling a direction of operations in read and/or write.

13. The electric apparatus as recited in claim 9, wherein the nonvolatile memory includes PCRAM, anti-fuse memory, MRAM, or RRAM.

14. The electric apparatus as recited in claim 9, further comprising a memory in addition to the first-type memory and the second-type memory.

15. The electric apparatus as recited in claim 9, wherein the non-volatile memory comprises:
a plurality of electrode layers in different height levels;
a plurality of memory material layers, disposed between the electrode layers, wherein the memory material has at least two physical states under different electric operation condition.

16. The electric apparatus as recited in claim 15, further comprising a plurality of steering elements disposed between the electrode layers and each of the steering elements electrically coupled to a corresponding one of the storage elements in series for controlling a direction of operations in read and/or write.

17. A memory structure, comprising:
a memory circuit structural base, formed over a substrate, wherein the memory circuit structural base has a planarized dielectric layer on top;
a plurality of first electrode layers, disposed over the dielectric layer;
a plurality of memory material layers, disposed on the first electrode layers at predetermined positions;
a plurality of second electrode layers, disposed on the memory material layers, to form a plurality of memory cells;
an inter-metal dielectric layer, over the memory cells;
a plurality of conductive lines, serving as bit lines, disposed over the inter-metal dielectric layer; and
a plurality of conductive via, in the inter-metal dielectric layer for respectively connecting the memory cells to the corresponding bit lines.

18. The memory structure as recited in claim 17, further comprising a packaging structure, over the memory circuit structural base to complete a single memory chip.

19. The memory structure as recited in claim 17, wherein the memory circuit structural base comprises a plurality of switch transistors and a plurality of word lines, the word lines control the switch transistors to be coupled to a ground voltage, and the switch transistors are respectively coupled to the corresponding memory cells, so as to generate an operation current or an operation bias crossing the memory material layer at a selected one of the memory cells.

20. A memory structure, comprising:
a circuit structure base over a substrate, wherein the circuit structure base comprises a plurality of switch transistors and a plurality of word lines, the word lines control the switch transistors to be coupled to a ground voltage;
a dielectric layer over the circuit structure base;
a plurality of first electrode layers, disposed over the dielectric layer;
a plurality of memory material layers, disposed on the first electrode layers at predetermined positions;
a plurality of second electrode layers, disposed on the memory material layers, to form a plurality of memory cells;
an inter-metal dielectric layer, over the memory cells;
a plurality of conductive lines, serving as bit lines, disposed over the inter-metal dielectric layer; and
a plurality of conductive via, in the inter-metal dielectric layer for respectively connecting the memory cells to the corresponding bit lines, to form a first memory.

21. The memory structure as recited in claim 20, further comprising a packaging structure, over the circuit structure base to complete a single memory chip.

22. The memory structure as recited in claim 21, further comprising a volatile memory structure formed over the inter-metal dielectric layer.
